(19) United States
(12) Patent Application Publication
(10) Pub. No.: US 2024/0200697 A1
(43) Pub. Date: Jun. 20, 2024

(54) TUBE FITTING

(71) Applicant: WOOJOO ENG Co., Ltd., Hwaseong-si (KR)

(72) Inventors: Yun Su WOO, Seoul (KR); Seong Jung KIM, Busan (KR); Hee Won JUNG, Jeonju-si (KR); Hun CHOI, Gyeonggi-do (KR)

(73) Assignee: WOOJOO ENG Co., Ltd., Hwaseong-si (KR)

(21) Appl. No.: 18/241,257

(22) Filed: Sep. 1, 2023

(30) Foreign Application Priority Data
Dec. 19, 2022 (KR) 10-2022-0178663

(51) Int. Cl. F16L 19/00; F16L 19/025

(52) U.S. Cl. CPC F16L 19/005; F16L 19/025

(57) ABSTRACT

A tube fitting includes a fitting body, a first coupling member configured to surround the fitting body, a fitting nut coupled to the fitting body, and a second coupling member provided on the fitting nut, wherein the first coupling member includes first coupling protrusions, and the second coupling member includes second coupling protrusions coming in contact with the first coupling protrusions while the fitting body and the fitting nut are coupled.

### CROSS-REFERENCE TO RELATED APPLICATION

This application claims priority to and the benefit of Korean Patent Application No. 2022-0178663, filed on Dec. 19, 2022, the disclosure of which is incorporated herein by reference in its entirety.

### BACKGROUND

### 1. Field of the Invention

The present disclosure relates to a tube fitting, and more particularly, to a tube fitting that is tightened to a required strength and prevented from loosening.

### 2. Discussion of Related Art

A tube fitting is a means for connecting between adjacent tubes and is used in a process in which a fluid is required (for example, a semiconductor process). Generally, a tube fitting includes a fitting body and a fitting nut coupled to each other and components provided between the fitting body and the fitting nut. The fitting body and the fitting nut should be tightened with sufficient strength. When the fitting body and the fitting nut are tightened less than required, a fluid flowing inside the tube fitting may leak, and the tube fitting may loosen due to vibrations generated in an environment in which the tube fitting is applied. When the fitting body and the fitting nut are tightened too tightly, the tube fitting (for example, the components provided between the fitting body and the fitting nut) may be damaged.

A worker tightens and couples the fitting body and the fitting nut directly by hand or using a tool. The worker may adjust the tightening strength by relying on the resistance felt when tightening the fitting body and the fitting nut. However, the resistance felt by each worker may be different, and even the same worker may feel the resistance differently according to circumstances. Therefore, the fitting body and the fitting nut may be tightened weaker or stronger than required.

### SUMMARY OF THE INVENTION

The present disclosure is directed to providing a tube fitting in which a fitting body and a fitting nut are coupled to a required strength.

The present disclosure is also directed to providing a tube fitting including a fitting body and a fitting nut that are prevented from loosening.

However, the objectives of the present disclosure are not limited to the above.

One aspect of the present disclosure provides a tube fitting including: a fitting body: a first coupling member configured to surround the fitting body: a fitting nut coupled to the fitting body: and a second coupling member provided on the fitting nut, wherein the first coupling member includes first coupling protrusions, and the second coupling member includes second coupling protrusions coming in contact with the first coupling protrusions while the fitting body and the fitting nut are coupled.

The first coupling protrusions may be configured to protrude from an inner circumferential surface of the first coupling member.

The first coupling member may further include a partition protruding from the inner circumferential surface, and the first coupling protrusions may protrude from the partition.

Each of the first coupling protrusions and the second coupling protrusions may include: a first surface having a relatively gentle slope: and a second surface having a relatively steep slope.

While the fitting body and the fitting nut are coupled to each other, the first surfaces of the first coupling protrusions and the second coupling protrusions may be configured to come in contact with each other, and while the fitting body and the fitting nut are separated from each other, the second surfaces of the first coupling protrusions and the second coupling protrusions may be configured to come in contact with each other.

While the fitting body and the fitting nut are coupled to each other to a required strength, the first coupling member and the second coupling member may be configured to come in contact with each other.

### BRIEF DESCRIPTION OF THE DRAWINGS

The above and other objects, features and advantages of the present disclosure will become more apparent to those of ordinary skill in the art by describing exemplary embodiments thereof in detail with reference to the accompanying drawings, in which:

FIG. 1 is a cross-sectional view of a tube fitting according to an exemplary embodiment:

FIG. 2 is an exploded perspective view of the tube fitting of FIG. 1:

FIG. 3 is a front view of a first coupling member of FIG. 1:

FIG. 4 is a rear view of the first coupling member of FIG. 1:

FIG. 5 is a perspective view of a second coupling member of FIG. 1:

FIG. 6 is a front view of the second coupling member of FIG. 1:

FIG. 7 is a rear view of the second coupling member of FIG. 1:

FIG. 8 is a front view of the first coupling member of FIG. 1 according to an exemplary embodiment:

FIG. 9 is a front view of the first coupling member of FIG. 1 according to an exemplary embodiment: and

FIG. 10 is a perspective view of a first fixing protrusion of FIG. 9.

### DETAILED DESCRIPTION OF EXEMPLARY EMBODIMENTS

Hereinafter, embodiments of the present disclosure will be described in detail with reference to the accompanying drawings. In the drawings, like reference numerals refer to like components, and the size of each component in the drawings may be exaggerated for clarity and convenience of description. Meanwhile, the embodiments described below are only illustrative, and various modifications are possible from the embodiments.

Hereinafter, being disposed “on” a certain component may not only mean being directly disposed on the component while in contact therewith, but also being disposed on the component while not in contact therewith. Hereinafter, “upper surface” may refer to a surface disposed at an upper side in the drawings. A singular expression includes a plural expression unless clearly indicated otherwise in the context. Also, when a certain part is described as “including” a certain component, unless particularly described otherwise, this means that the part may further include other components instead of excluding other components.

Also, terms such as “part” used herein refers to a unit of processing at least one function or operation.

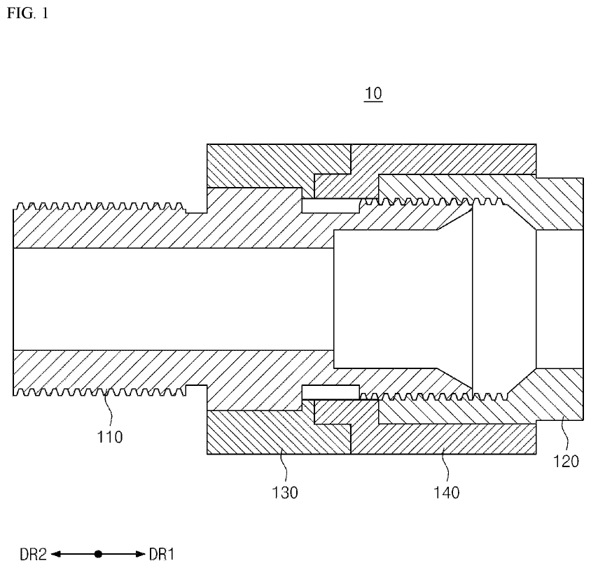

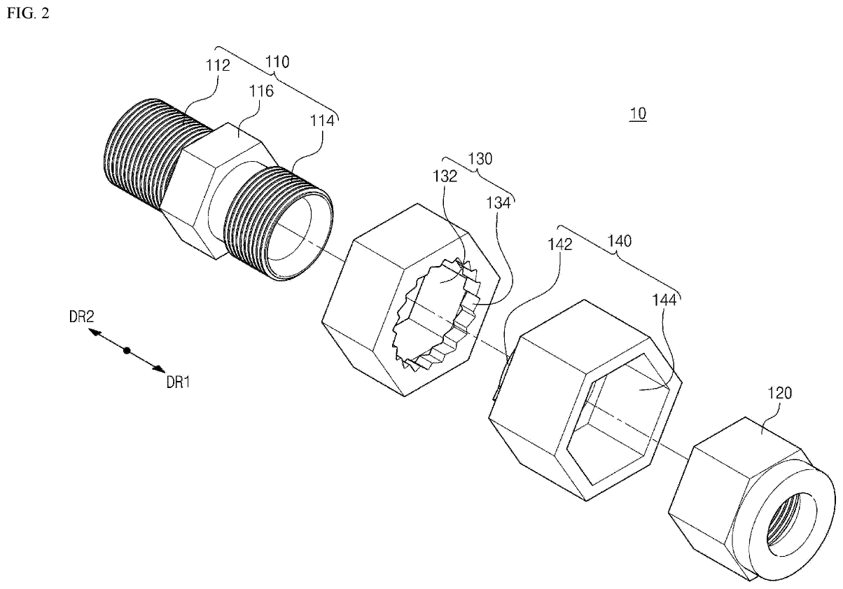

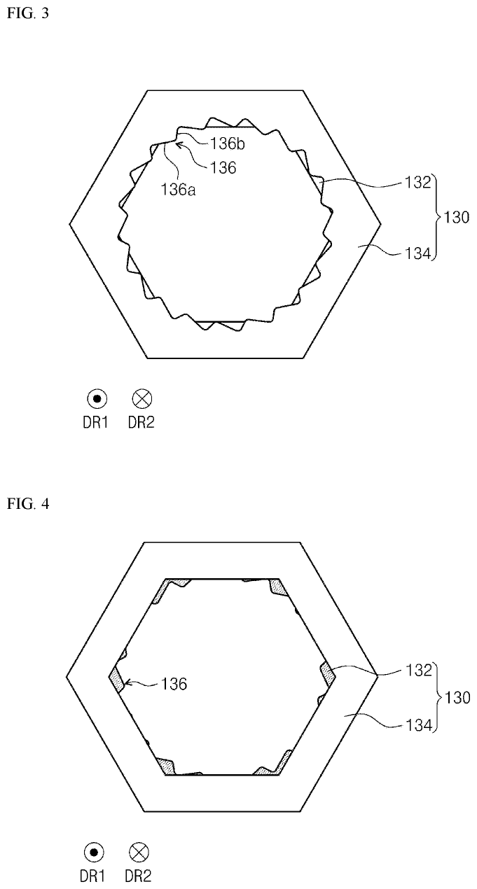

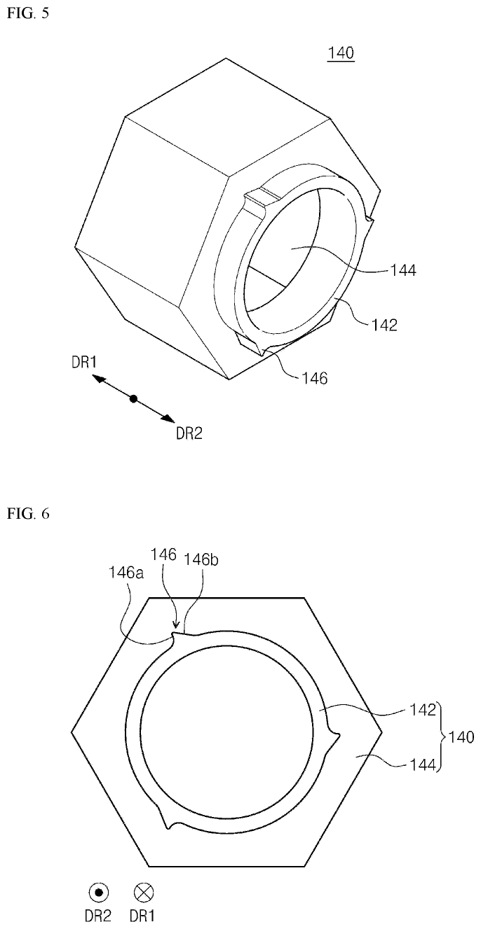

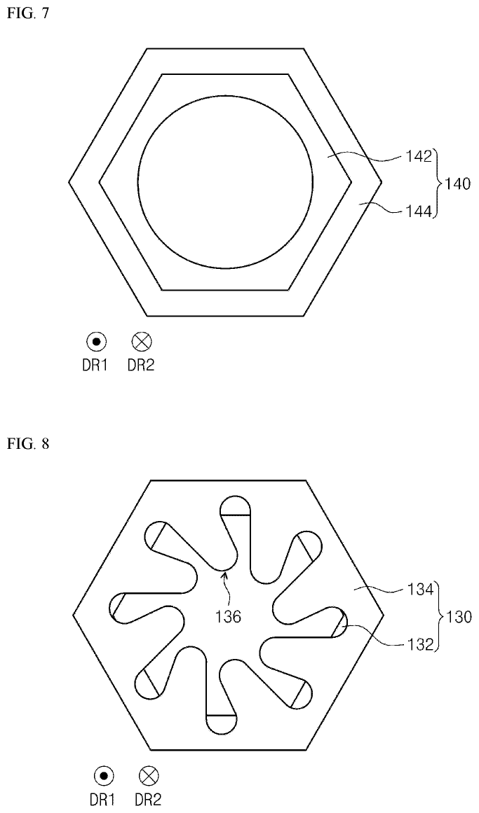

FIG. 1 is a cross-sectional view of a tube fitting according to an exemplary embodiment. FIG. 2 is an exploded perspective view of the tube fitting of FIG. 1. FIG. 3 is a front view of a first coupling member of FIG. 1. FIG. 4 is a rear view of the first coupling member of FIG. 1. FIG. 5 is a perspective view of a second coupling member of FIG. 1. FIG. 6 is a front view of the second coupling member of FIG. 1. FIG. 7 is a rear view of the second coupling member of FIG. 1.

Referring to FIGS. 1 and 2, a tube fitting 10 may be provided. The tube fitting 10 may be provided between a first tube (not illustrated) and a second tube (not illustrated), which are different from each other, to connect the tubes. The tube fitting 10 may include a fitting body 110, a fitting nut 120, a first coupling member 130, and a second coupling member 140. The fitting body 110 may include a first portion 112 coupled to the first tube, a second portion 114 coupled to the fitting nut 120, and a third portion 116 onto which the first coupling member 130 is fitted. The first portion 112 may have a hollow shape that extends in a first direction DR1. Screw threads may be formed on an outer circumferential surface of the first portion 112 and screw-coupled to the first tube. The second portion 114 may be spaced apart from the first portion 112 in the first direction DR1. The second portion 114 may have a hollow shape that extends in the first direction DR1. Screw threads may be formed on an outer circumferential surface of the second portion 114 and screw-coupled to the fitting nut 120. The third portion 116 may have the shape of a polygonal nut. For example, the third portion 116 may have the shape of a hexagonal nut. The third portion 116 may be fitted and coupled to the first coupling member 130. The first portion 112, the third portion 116, and the second portion 114 may communicate in the first direction DR1. The fitting body 110 is not limited to the illustrated shape and may have various other shapes that allow the fitting body 110 to be coupled to the first tube, the first coupling member 130, and the fitting nut 120.

The fitting nut 120 may be coupled to the fitting body 110. Screw threads coupled to the screw threads formed on the outer circumferential surface of the second portion 114 may be formed on an inner circumferential surface of the fitting nut 120. The fitting nut 120 may be coupled to the second tube. The second tube may be provided at the opposite side of the fitting body 110 relative to the fitting nut 120. For example, the fitting nut 120 may be fitted and coupled to the second tube. The first tube and the second tube may communicate with each other by the fitting body 110 and the fitting nut 120.

The first coupling member 130 may be provided on the third portion 116 of the fitting body 110. Referring to FIGS. 2 to 4, the first coupling member 130 may have the shape of a nut. Although the first coupling member 130 is illustrated as having the shape of a hexagonal nut, this is only illustrative. In another example, the first coupling member 130 may have the shape of a polygonal nut other than a hexagonal nut. The first coupling member 130 may have flexibility. For example, the first coupling member 130 may include a resin (for example, polypropylene (PP), polytetrafluoroethylene (PTFE), polyethylene (PE), polycarbonate (PC)) or silicone. In the case in which the first coupling member 130 includes silicone, a shore hardness may be in a range of 80 to 100°. When coupling and loosening of the fitting body 110 and the fitting nut 120 are repeated, the first coupling member 130 and the second coupling member 140 may be deformed. In the case in which the first coupling member 130 includes silicone having a shore hardness in a range of 80 to 100°, the first coupling member 130 may maintain its original shape despite repeated coupling and loosening of the fitting body 110 and the fitting nut 120. Accordingly, the first coupling member 130 may be used multiple times. The first coupling member 130 may include a first fitting portion 132 and a first fixing portion 134. The first fitting portion 132 and the first fixing portion 134 may be portions of the first coupling member 130 that have different inner peripheral surface shapes. The first fitting portion 132 and the first fixing portion 134 may be sequentially disposed in the first direction DR1. The first fitting portion 132 may provide an area into which the third portion 116 of the fitting body 110 is inserted. The first fitting portion 132 may have an inner peripheral surface having a shape that corresponds to an outer peripheral surface of the third portion 116. When the third portion 116 is inserted into the first fitting portion 132, the outer peripheral surface of the third portion 116 and the inner peripheral surface of the first fitting portion 132 may face each other. When the third portion 116 of the fitting body 110 is inserted into the first fitting portion 132, the first coupling member 130 may be prevented from rotating independently of the fitting body 110.

The first fixing portion 134 may include first fixing protrusions 136 arranged along an inner circumferential surface. For example, the first fixing protrusions 136 may be continuously arranged. The first fixing protrusions 136 may protrude toward an inner area of the first fixing portion 134. Since the first fixing protrusions 136 have substantially the same shape, a single first fixing protrusion 136 will be described. The first fixing protrusion 136 may include a first surface 136a and a second surface 136b that form a certain angle. The first surface 136a and the second surface 136b may extend in the first direction DR1. When viewed along a second direction DR2 opposite to the first direction DR1, the first surface 136a and the second surface 136b may be arranged clockwise. The first surface 136a may have a relatively gentle slope, and the second surface 136b may have a relatively steep slope. The slope may be a slope relative to a plane passing a lower boundary of the first surface 136a and a lower boundary of the second surface 136b. A boundary line between the first surface 136a and the second surface 136b may be disposed to be biased toward the second surface 136b from the center of the first fixing protrusion 136 when viewed along the second direction DR2. In one example, an area where the first surface 136a and the second surface 136b meet may form a curved surface. In this case, the boundary line between the first surface 136a and the second surface 136b may refer to a line whose slope is 0.

The first fitting portion 132 and the first fixing portion 134 may partially overlap in the first direction DR1 or the second direction DR2. One portion of the first fitting portion 132 may overlap with the first fixing portion 134 in the first direction DR1, and the other portion of the first fitting portion 132 may not overlap with the first fixing portion 134 in the first direction DR1. One portion of the first fixing portion 134 may overlap with the first fitting portion 132 in the second direction DR2, and the other portion of the first fixing portion 134 may not overlap with the first fitting portion 132 in the second direction DR2. For example, some of the first fixing protrusions 136 may protrude from the inner circumferential surface of the first fitting portion 132. The third portion 116 of the fitting body 110 may be inserted into the first fitting portion 132 and may directly come in contact, in the first direction DR1, with some of the first fixing protrusions 136 protruding from the inner circumferential surface of the first fitting portion 132.

Referring to FIG. 2 and FIGS. 5 to 7, the second coupling member 140 may have the shape of a nut. Although the second coupling member 140 is illustrated as having the shape of a hexagonal nut, this is only illustrative. In another example, the second coupling member 140 may have the shape of a polygonal nut other than a hexagonal nut. The second coupling member 140 may have flexibility. For example, the second coupling member 140 may include a resin (for example, polypropylene (PP), polytetrafluoroethylene (PTFE), polyethylene (PE), polycarbonate (PC)) or silicone. In the case in which the second coupling member 140 includes silicone, a shore hardness may be in a range of 80 to 100°. When coupling and loosening of the fitting body 110 and the fitting nut 120 are repeated, the first coupling member 130 and the second coupling member 140 may be deformed. In the case in which the second coupling member 140 includes silicone having a shore hardness in a range of 80 to 100°, the second coupling member 140 may maintain its original shape despite repeated coupling and loosening of the fitting body 110 and the fitting nut 120. Accordingly, the second coupling member 140 may be used multiple times. The second coupling member 140 may include a second fixing portion 142 and a second fitting portion 144. The second fixing portion 142 and the second fitting portion 144 may be sequentially disposed in the second direction DR2.

The second fixing portion 142 may have the shape of a circular ring including second fixing protrusions 146 arranged along an outer circumferential surface. For example, the second fixing protrusions 146 may be arranged at predetermined intervals. Although the second fixing portion 142 is illustrated as including three second fixing protrusions 146, this is only illustrative. In another example, the second fixing portion 142 may include fewer than three or more than three second fixing protrusions 146. Since the second fixing protrusions 146 have substantially the same shape, a single second fixing protrusion 146 will be described. The second fixing protrusion 146 may include a first surface 146a and a second surface 146b that form a certain angle. The first surface 146a and the second surface 146b may extend in the first direction DR1. When viewed along the first direction DR1, the first surface 146a and the second surface 146b may be arranged clockwise. The first surface 146a may have a relatively gentle slope, and the second surface 146b may have a relatively steep slope. The slope may be a slope relative to a plane passing a lower boundary of the first surface 146a and a lower boundary of the second surface 146b. A boundary line between the first surface 146a and the second surface 146b may be disposed to be biased toward one side from the center of the second fixing protrusion 146 when viewed along the first direction DR1. In one example, an area where the first surface 146a and the second surface 146b meet may form a curved surface. In this case, the boundary line between the first surface 146a and the second surface 146b may refer to a line whose slope is 0.

The second fitting portion 144 may provide an area into which the fitting nut 120 is inserted. The second fitting portion 144 may have an inner peripheral surface having a shape that corresponds to an outer peripheral surface of the fitting nut 120. When the fitting nut 120 is inserted into the second fitting portion 144, the outer peripheral surface of the fitting nut 120 and the inner peripheral surface of the second fitting portion 144 may face each other. In a state in which the fitting nut 120 is inserted into the second fitting portion 144, the second coupling member 140 may be prevented from rotating independently of the fitting nut 120.

The fitting nut 120 may rotate clockwise and may be screw-coupled to the fitting body 110. The second coupling member 140 and the first coupling member 130 coupled to the fitting nut 120 and the fitting body 110, respectively, may also rotate together. The fitting nut 120 may approach the fitting body 110 by rotating clockwise until the first surface 146a of the second fixing protrusion 146 comes in contact with the first surface 136a of the first fixing protrusion 136. Since the second fixing protrusion 146 and the first fixing protrusion 136 have flexibility, when a force that causes clockwise rotation is applied to the second coupling member 140 in a state in which the first surface 146a of the second fixing protrusion 146 is in contact with the first surface 136a of the first fixing protrusion 136, at least one of the second fixing protrusion 146 and the first fixing protrusion 136 may be deformed. Accordingly, the second fixing protrusion 146 may pass by the first fixing protrusion 136.

The screw coupling process of the fitting body 110 and the fitting nut 120 of the present disclosure may be performed until the second coupling member 140 comes in contact with the first coupling member 130. The fitting body 110 and the fitting nut 120 may be configured to be tightened to a required strength when the first coupling member 130 comes in contact with the second coupling member 140. A worker may easily tighten the fitting body 110 and the fitting nut 120 to a required strength without relying on his/her senses. A case in which the fitting body 110 and the fitting nut 120 are tightened weaker or stronger than the required strength may be reduced or prevented. Accordingly, damage to components provided between the fitting body 110 and the fitting nut 120 may be prevented.

An environment in which the tube fitting 10 is installed may be prone to vibrations. When vibrations are transmitted to the tube fitting 10, screw coupling may loosen. The first fixing protrusions 136 and the second fixing protrusions 146 of the present disclosure may be configured so that the fitting body 110 and the fitting nut 120 are easily coupled but difficult to loosen. In a state in which the fitting nut 120 is coupled to the fitting body 110, when the fitting nut 120 rotates counterclockwise, the fitting nut 120 may be loosened from the fitting body 110. Unlike when the fitting nut 120 rotates clockwise, the second surface 146b of the second fixing protrusion 146 may come in contact with the second surface 136b of the first fixing protrusion 136 as the fitting nut 120 rotates counterclockwise. Since the second fixing protrusion 146 and the first fixing protrusion 136 have flexibility, when a force that causes counterclockwise rotation is applied to the second coupling member 140 in a state in which the second surface 146b of the second fixing protrusion 146 is in contact with the second surface 136b of the first fixing protrusion 136, the second fixing protrusion 146 may pass by the first fixing protrusion 136. Since the second surfaces 136b and 146b of the first and second fixing protrusions 136 and 146 have a relatively steep slope, for the second fixing protrusion 146 to rotate counterclockwise and pass by the first fixing protrusion 136, a greater force may be required compared to when the second fixing protrusion 146 rotates clockwise and passes by the first fixing protrusion 136. In other words, a greater force may be required when the fitting nut 120 and the fitting body 110 are loosened than when the fitting nut 120 and the fitting body 110 are tightened. As a result, the tube fitting 10 of the present disclosure may be configured to be prevented from loosening in an environment prone to vibrations.

FIG. 8 is a front view of the first coupling member of FIG. 1 according to an exemplary embodiment. For conciseness of description, differences from the above description with reference to FIG. 3 will be described.

Referring to FIG. 8, the first coupling member 130 may be provided. The first coupling member 130 may include the first fitting portion 132 and the first fixing portion 134. Unlike in the above description with reference to FIG. 3, the first fixing protrusions 136 may have a shape that is tilted clockwise.

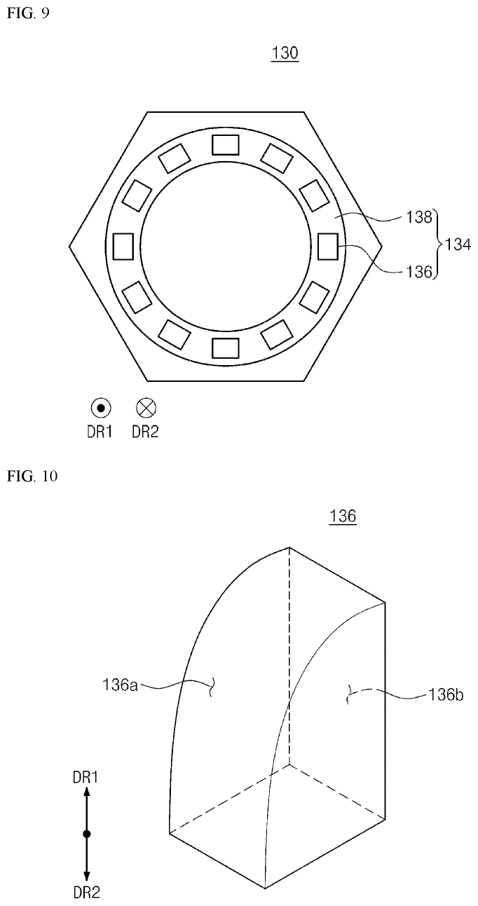

FIG. 9 is a front view of the first coupling member of FIG. 1 according to an exemplary embodiment. FIG. 10 is a perspective view of a first fixing protrusion of FIG. 9. For conciseness of description, differences from the above description with reference to FIG. 3 will be described.

Referring to FIG. 9, the first coupling member 130 may be provided. The first coupling member 130 may include a first fitting portion (not illustrated) and the first fixing portion 134. Unlike in the above description with reference to FIG. 3, the first fixing portion 134 may further include a partition 138. The partition 138 may be provided between the first fixing protrusions 136 and the first fitting portion. The partition 138 may provide an area in which the first fixing protrusions 136 are disposed.

The first fixing protrusions 136 may protrude from the partition 138 in the first direction DR1. The first fixing protrusions 136 may include the first surface 136a having a gentle slope and the second surface 136b having a steep slope. The first surface 136a and the second surface 136b may be arranged clockwise when viewed along the second direction DR2.

The present disclosure can provide a tube fitting in which a fitting body and a fitting nut are coupled to a required strength.

The present disclosure can provide a tube fitting including a fitting body and a fitting nut that are prevented from loosening.

However, the advantageous effects of the present disclosure are not limited to the above.

The above description of the embodiments of the technical spirit of the present disclosure provides examples for description of the technical spirit of the present disclosure. Therefore, the technical spirit of the present disclosure is not limited to the above embodiments, and it is apparent that many modifications and changes, such as carrying out the above embodiments in combination, are possible by those of ordinary skill in the art within the technical spirit of the present disclosure.

What is claimed is:

1. A tube fitting comprising:
a fitting body;
a first coupling member configured to surround the fitting body and having flexibility;
a fitting nut coupled to the fitting body; and
a second coupling member provided on the fitting nut and having flexibility,
wherein the fitting body includes a first portion coupled to a fitting tube, a second portion coupled to the fitting nut, and a third portion onto which the first coupling member is fitted,
the first coupling member includes a first fitting portion configured to provide an area into which the third portion is inserted and a first fixing portion including first fixing protrusions,
the second coupling member includes a second fixing portion including second fixing protrusions that come in contact with the first fixing protrusions while the fitting body and the fitting nut are coupled and a second fitting portion configured to provide an area into which the fitting nut is inserted,
the first fixing portion and the second fixing portion are configured to extend to an area between the third portion and the fitting nut, and
when the fitting body and the fitting nut are coupled to a required strength, the first coupling member and the second coupling member come in contact with each other.

2. The tube fitting of claim 1, wherein:
the first fixing protrusions are configured to include a first surface having a relatively gentle slope and a second surface having a relatively steep slope; and
the second fixing protrusions are configured to come in contact with the first surface of the first fixing protrusion when the fitting body and the fitting nut are coupled and come in contact with the second surface of the first fixing protrusion when the fitting body and the fitting nut are loosened.

3. The tube fitting of claim 1, wherein:
the first coupling member further includes a partition configured to protrude from an inner circumferential surface of the first fitting portion; and
the first fixing protrusions protrude from the partition in a direction in which the fitting body and the fitting nut are arranged.

4. The tube fitting of claim 1, wherein:
the first fixing protrusions are configured to include a first surface having a relatively gentle slope and a second surface having a relatively steep slope;
the second fixing protrusions are configured to include a third surface having a relatively gentle slope and a fourth surface having a relatively steep slope;
the third surface of the second fixing protrusion is configured to come in contact with the first surface of the first fixing protrusion when the fitting body and the fitting nut are coupled; and
the fourth surface of the second fixing protrusion is configured to come in contact with the second surface of the first fixing protrusion when the fitting body and the fitting nut are loosened.
